(19) United States
(12) Patent Application Publication
(10) Pub. No.: US 2006/0024938 A1
(43) Pub. Date: Feb. 2, 2006

(54) Method for reducing metal silicide excessive encroachment defects in the manufacture of a semiconductor device having silicided source/drain regions

(75) Inventors: Duofeng Yue, Plano, TX (US); Peijun J. Chen, Dallas, TX (US); Jiong-Ping Lu, Richardson, TX (US); Thomas D. Bonifield, Dallas, TX (US); Noel M. Russell, Plano, TX (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 10/901,697

(22) Filed: Jul. 29, 2004

(51) Int. Cl. H01L 21/336; H01L 21/3205; H01L 21/4763

(52) U.S. Cl. 438/595; 438/300; 438/592; 438/303; 438/305

(57) ABSTRACT

The present invention provides a method for manufacturing a semiconductor device, and a method for manufacturing an integrated circuit including the semiconductor device, and a semiconductor device. The method for manufacturing a semiconductor device, among other steps, includes forming source/drain regions (290) in a substrate (210), the source/drain regions (290) located proximate a gate structure having sidewall spacers (270) and positioned over the substrate (210), and modifying a footprint of the sidewall spacers (270) by forming protective regions (410) proximate a base of the sidewall spacers (270). The method further includes forming metal silicide regions (610) in the source/drain regions (290).

### TECHNICAL FIELD OF THE INVENTION

The present invention is directed, in general, to a method for manufacturing a semiconductor device, and, more specifically, to a method for reducing metal silicide excessive encroachment defects in the manufacture of a semiconductor device having silicided source/drain regions and a method for manufacturing an integrated circuit including the same.

### BACKGROUND OF THE INVENTION

Conventional metal-oxide-semiconductor (MOS) transistors often use metal silicide layers to reduce resistance. A self aligned silicidation process (salicide) is often used to form the region of titanium, cobalt or tungsten silicide on the gate electrode and source/drain regions of the MOS transistor. In this process, a blanket metal film is deposited on the silicon substrate containing the MOS transistor structure. The metal is then reacted with the underlying silicon regions to form a low resistance metal silicide. Any unreacted metal remaining on the substrate is then removed using a metal etch process that is selective to the remaining metal silicide.

In order to reduce the resistances associated with the metal silicide regions, nickel is finding increasing use in forming the metal silicide regions in MOS transistors, particularly for transistors with physical gate lengths of less than 40 nm and/or MOS transistors with ultra-shallow junctions. Nickel has a very high diffusivity in silicon leading to the formation of nickel silicide regions that extend beneath the transistor sidewall structures. Unfortunately, the nickel silicide regions that extend beneath the transistor sidewall structures tend to lead to nickel silicide excessive encroachment defects extending into the channel region of the MOS transistor. As would be expected, the excessive encroachment defects that extend into the channel region tend to cause serious device yield problems.

There is therefore a need for a method to form metal silicide regions on the source/drain regions of a MOS transistor that do not extend under the transistor sidewall structures, thereby causing the undesirable metal silicide excessive encroachment defects.

### SUMMARY OF THE INVENTION

To address the above-discussed deficiencies of the prior art, the present invention provides a method for manufacturing a semiconductor device, a method for manufacturing an integrated circuit including the semiconductor device, and a semiconductor device. The method for manufacturing a semiconductor device, among other steps, includes forming source/drain regions in a substrate, the source/drain regions located proximate a gate structure having sidewall spacers and positioned over the substrate, and modifying a footprint of the sidewall spacers by forming protective regions proximate a base of the sidewall spacers. The method further includes forming metal silicide regions in the source/drain regions.

The method for manufacturing the integrated circuit, in addition to that discussed above, includes the step of forming interconnects within dielectric layers located over the substrate for electrically contacting the semiconductor devices.

As previously mentioned, the present invention further includes a semiconductor device. The semiconductor device of the present invention, without limitation, includes: (1) a gate structure having sidewall spacers located over a substrate, (2) source/drain regions located in the substrate and proximate the gate structure, and (3) metal silicide regions located in the source/drain regions, the metal silicide regions having a main portion and an offset portion.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates a cross-sectional view of a semiconductor device that was constructed according to the principles of the present invention;

FIG. 2 illustrates a cross-sectional view of a partially completed semiconductor device manufactured in accordance with the principles of the present invention;

FIG. 3 illustrates a cross-sectional view of the partially completed semiconductor device illustrated in FIG. 2 after forming a layer of protective material over the gate structure having sidewall spacers and the source/drain regions;

FIG. 4 illustrates a cross-sectional view of the partially completed semiconductor device illustrated in FIG. 3 after subjecting the layer of protective layer to an etch, thereby forming protective regions;

FIG. 5 illustrates a cross-sectional view of the partially completed semiconductor device illustrated in FIG. 5 after forming a metal layer over the gate electrode layer and source/drain regions;

FIG. 6 illustrates a cross-sectional view of the partially completed semiconductor device illustrated in FIG. 5 after subjecting the metal layer to an anneal, thereby causing the metal layer to react with the underlying silicon regions to form metal silicide regions, and thereafter removing any remaining portions of the metal layer; and

FIG. 7 illustrates a sectional view of a conventional integrated circuit (IC) incorporating a semiconductor device constructed according to the principles of the present invention.

### DETAILED DESCRIPTION

As physical gate lengths continue to decrease in metal-oxide-semiconductor (MOS) devices, especially those below the 40 nm level, certain obstacles must be overcome to continue using nickel as a metal silicide for contacting conventional source/drain regions. One of those obstacles includes excessive encroachment defects extending underneath the sidewall spacer of the semiconductor device. The present invention, in contrast to the prior art, has recognized that the excessive encroachment defects are at least partially a function of the larger than normal buildup of the silicidation metal at the base of the sidewall spacers where they meet the substrate, which occurs prior to the formation of the metal silicide regions. It is believed that this buildup provides an increased amount of metal, particularly nickel, into the substrate at this junction. Accordingly, the metal (e.g., nickel) is more likely to diffuse under the sidewall spacers and cause the unwanted excessive encroachment defects during the silicidation process.

Given this obstacle, as well as the aforementioned recognition, the present invention identified that protective regions could be formed at a base of the sidewall spacers to modify a footprint thereof, and thereby remove the buildup of silicidation metal at the junction of the sidewall spacers and the substrate. It has been observed that while the buildup of silicidation metal may still occur at the base of the protective regions, this location is removed a sufficient distance away from the channel region to substantially reduce the possibility and number of excessive encroachment defects.

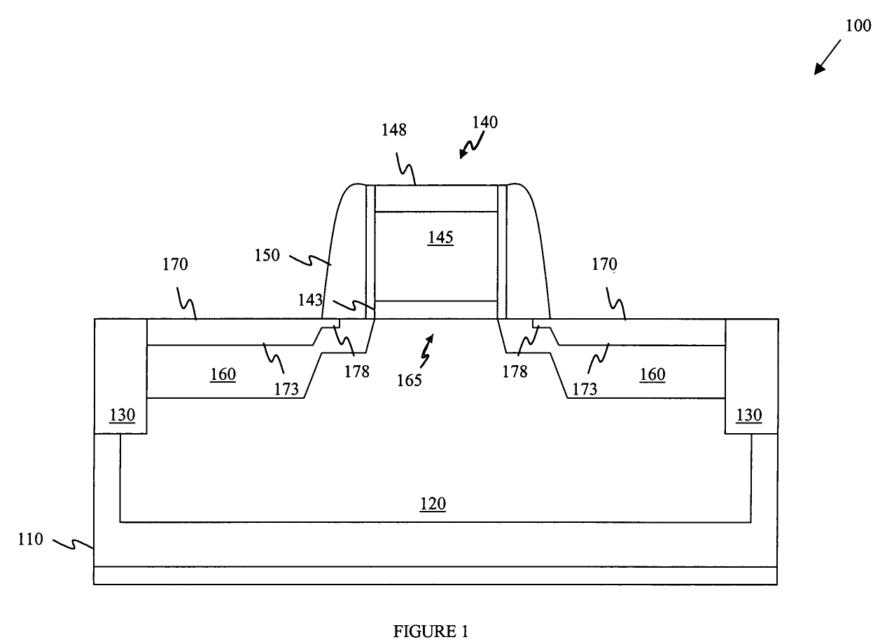

Turning to FIG. 1, illustrated is a cross-sectional view of a semiconductor device 100 that was constructed according to the principles of the present invention. The semiconductor device 100 of FIG. 1 initially includes a substrate 110 having a well region 120 located therein. Located over the well region 120, and separated by isolation structures 130, is a gate structure 140. The gate structure 140 includes a gate dielectric layer 143, a gate electrode layer 145, and a silicided gate electrode layer 148. Flanking both sides of the gate structure 140 are sidewall spacers 150. While it is illustrated in FIG. 1 that the sidewall spacers 150 comprise multiple layers, such is not always the case.

Located within the substrate 110 and proximate the gate structure 140 are source/drain regions 160. The source/drain regions 160, as is appreciated by one skilled in the art, are separated from one another by a distance, thereby forming a channel region 165. Positioned within the source/drain regions 160 are metal silicide regions 170. The metal silicide regions 170, which were manufactured in accordance with the unique method of the present invention, have a main portion 173 and an offset portion 178. For example, in one embodiment of the invention the metal silicide regions 170 have a substantially stepped cross-section. This is in direct contrast to the prior art structures that have a uniform or gradually changing cross-section. As used herein, the term “stepped cross-section” means they have a shape similar to stair steps. Given the stepped cross-section, the metal silicide regions 170 have multiple plateaus. The stepped cross-section is but one embodiment of the dual portion metal silicide regions 170.

In the illustrative embodiment of FIG. 1, the cross-section of the metal silicide regions 170 only have two steps. In an embodiment such as this, a first step of the metal silicide regions 170 may advantageously be located under the sidewall spacers 150 and a second step may advantageously be located outside the footprint of the sidewall spacers 150. In this embodiment, the first step might be much shallower than the second step, as shown in FIG. 1. The specific depths of each step depend on the original deposited metal thickness.

As previously mentioned, the stepped cross-section of the metal silicide regions 170 is a function of the methodology used to form the metal silicide regions 170. Nevertheless, this stepped cross-section advantageously allows the metal silicide regions 170 to be distanced away from the channel region 165, thereby reducing if not elimination excessive encroachment defect issues.

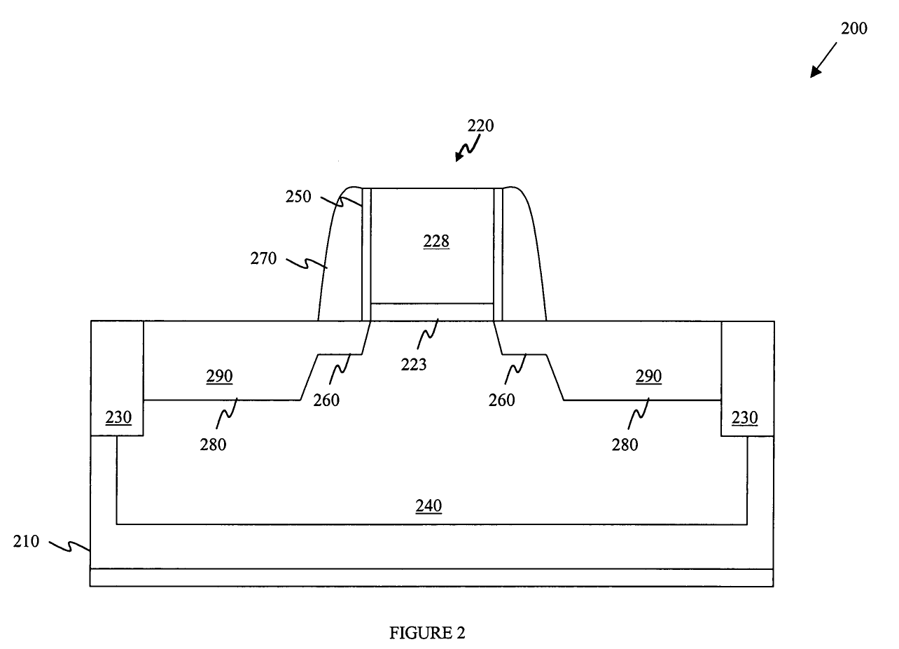

Turning now to FIGS. 2-6, illustrated are cross-sectional views of detailed manufacturing steps instructing how one might, in an advantageous embodiment, manufacture a semiconductor device in accordance with the principles of the present invention. The partially completed semiconductor device 200 of FIG. 2 includes a substrate 210. The substrate 210 may, in an exemplary embodiment, be any layer located in the partially completed semiconductor device 200, including a wafer itself or a layer located above the wafer (e.g., epitaxial layer).

As is illustrated in FIG. 2, a gate structure 220 is formed over the substrate 210. The gate structure 220, in the embodiment shown, includes a gate dielectric layer 223 and a gate electrode layer 228. The gate dielectric layer 223 may, for example, comprise an oxide, thermally grown SiO₂, a nitride, an oxynitride, or any combination thereof, and preferably has a thickness ranging from about 1 nm to about 20 nm. The gate dielectric layer 223 can also be formed using a high K dielectric material with a dielectric constant greater than about 3.9. Some examples of high K dielectric material include hafnium containing dielectrics such as hafnium oxide, hafnium oxynitride, etc.

As previously indicated, the gate structure 220 further includes a gate electrode layer 228. The gate electrode layer 228 in one advantageous embodiment comprises a layer of silicon-containing material formed on the gate dielectric layer 223. Preferably, this silicon-containing material is comprised of polycrystalline silicon (“poly” or “polysilicon”), but it may comprise amorphous silicon, epitaxial silicon or any other semiconducting material.

Located within the substrate 210 and between isolation regions 230 is a well region 240. The well region 240 in the substrate 210 shown in FIGS. 2-6 can be either n-type or p-type. In forming CMOS integrated circuits, n-type and p-type well regions 240 are formed in the substrate 210. In the case of a p-well region, an NMOS transistor will be formed. In a similar manner for an n-well region, a PMOS transistor will be formed.

With the gate structure 220 defined using standard photolithography processes and polysilicon etching, a spacer 250 is formed, for example, by first thermally growing about 1 nm to about 5 nm of oxide followed by depositing about 15 nm of TEOS oxide. In other embodiments the spacer 250 can comprise a combination of silicon nitride and/or silicon oxide (either grown or deposited) layers. Depending on certain criteria, which will be discussed further below, one certain embodiment of the invention has the spacer 250 comprising a nitride and deposited using bis t-butylaminosilane (BTBAS) and ammonia (NH₃) precursors in a CVD reactor. Advantageously, the carbon causes the spacer 250 to etch at a slower rate than a traditional nitride layer. In an exemplary situation, after having been annealed using a temperature ranging from about 1000° C. to about 1100° C., the carbon causes the spacer 250 to have an etch selectivity of about 50:1 when compared to the traditional nitride layer. Again, the importance of this will be discussed further below.

For an NMOS transistor where the well region 240 comprises a portion of a p-type well, a blanket n-type lightly doped implant is performed resulting in the lightly doped extension implants 260. The n-type lightly doped extension implants 260 are often referred to as a lightly doped drain (LDD) or a moderately doped drain (MDD) extension regions. The n-type lightly doped extension implants 260 are conventionally formed and generally have a peak dopant concentration ranging from about 1E19 atoms/cm³ to about 2E20 atoms/cm³.

In addition to the n-type lightly doped extension implants 260, pocket implants (not shown) are sometimes performed. For the case where the semiconductor device 200 shown in FIG. 2 is an NMOS transistor, the pocket implants would comprise a p-type dopant species. In current integrated circuit technology, pocket implants refer to an implant that is used to reduce the effect of the short transistor gate length on transistor properties such as threshold voltage. The effect of the pocket implant is not however limited to threshold voltage. The pocket implant for a particular transistor type usually results in a doping profile that extends beyond the drain extension of the transistor. The species of the p-type pocket implant can consist of B, BF₂, Ga, In, or any other suitable p-type dopant. The species of the n-type lightly doped extension implants 260 implant can consist of As, P, Sb, or any other suitable n-type dopant. The order of the implants is somewhat arbitrary and the n-type lightly doped extension implants 260 could be performed before the pocket implant.

For a PMOS transistor where well region 240 comprises a portion of a n-type well, a blanket p-type lightly doped implant is performed resulting in p-type lightly doped extension implants 260. The p-type lightly doped extension implants 260 are also often referred to as a lightly doped drain (LDD) or a moderately doped drain (MDD) extension region. The p-type lightly doped extension implants 260 are conventionally formed and generally have a peak dopant concentration ranging from about 1E19 atoms/cm³ to about 2E20 atoms/cm³.

In addition to the p-type lightly doped extension implants 260, pocket implants are sometimes performed. For the case where the transistor shown in FIG. 2 is a PMOS transistor, the pocket implant would comprise an n-type dopant species. In current integrated circuit technology, pocket implants refer to an implant that is used to reduce the effect of the short transistor gate length on transistor properties such as threshold voltage. The effect of the pocket implant is not however limited to threshold voltage. The pocket implant for a particular transistor type usually results in a doping profile that extends beyond the drain extension of the transistor. The species of the n-type pocket implant can consist of As, P or any other suitable n-type dopant. The species of the p-type lightly doped extension implants 260 can consist of boron or any other suitable p-type dopant. The order of the implants is somewhat arbitrary and the pocket implant can be performed before the p-type lightly doped extension implants 260.

After the completion of the lightly doped extension implants 260 (and pocket implant if performed), and any subsequent processing, sidewall spacers 270 are formed as shown in FIG. 2. In an embodiment of the instant invention, the sidewall spacers 270 comprise a plurality of silicon oxide and silicon nitride dielectric layers. The sidewall spacers 270 are formed by first depositing blanket layers of suitable dielectric material. An anisotropic etch is then used to form the sidewall spacers 270. The sidewall spacers 270 can also be formed using a single suitable dielectric material such as silicon nitride or silicon oxide.

Following the formation of the sidewall spacers 270, highly doped source/drain implants 280 are formed. For an NMOS transistor, n-type dopants such as arsenic and/or phosphorous are implanted into the substrate 210 adjacent to the sidewall spacers 270 to form the highly doped source/drain implants 280. For a PMOS transistor, p-types dopants such as boron are implanted into the substrate 210 adjacent to the sidewall spacers 270 to form the highly doped source/drain implants 280. The highly doped source/drain implants 280 are conventionally formed and generally have a peak dopant concentration ranging from about 1E18 atoms/cm³ to about 1E21 atoms/cm³.

Following the formation of the highly doped source/drain implants 280, a high temperature source/drain anneal may be performed to activate the implanted dopants and remove the damage to the substrate 210 created during the ion implantation process. What results are source/drain regions 290. The source/drain anneal can comprise a rapid thermal annealing (RTA) process where the source/drain regions 290 are annealed at temperatures above 800° C. for times ranging from a second to minutes.

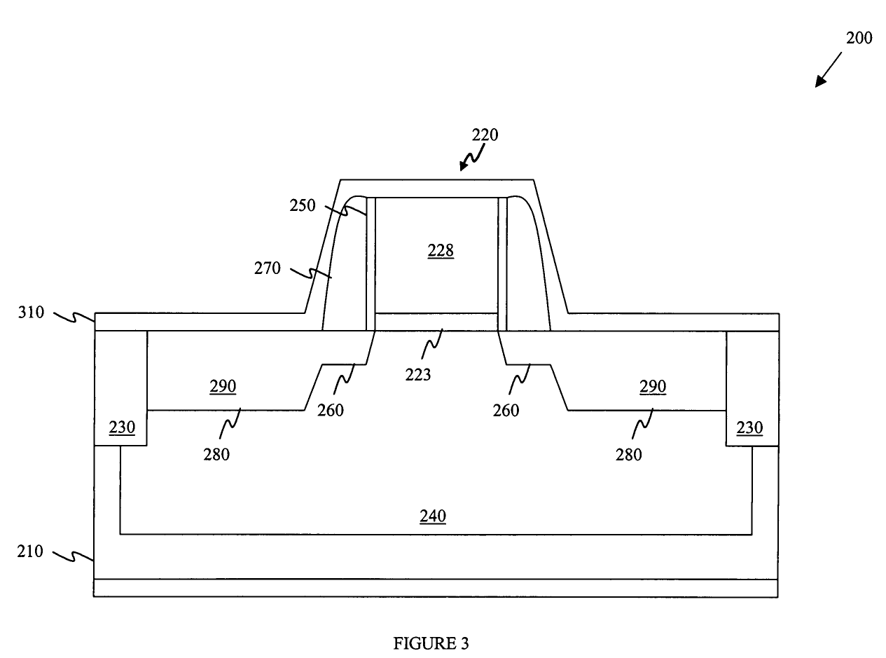

Turning now to FIG. 3, illustrated is a cross-sectional view of the partially completed semiconductor device illustrated in FIG. 2 after forming a layer of protective material 310 over the gate structure 220 having sidewall spacers 270 and the source/drain regions 290. The layer of protective material 310 may comprise a plurality of different materials while staying within the scope of the present invention. Of the many different materials, the layer of protective material 310 most notably may comprise a nitride or an oxide.

In the case of the layer of protective material 310 comprising a nitride, it may be a thin layer of chemical vapor deposition (CVD) nitride having a thickness ranging from about 1 nm to about 10 nm, and more specifically from about 2 nm to about 5 nm. In the case of the layer of protective material 310 comprising an oxide, it may be a thin layer of deposited, or if possible, grown oxide having a similar thickness. Again, the layer of protective material 310 may comprise other materials than a nitride or an oxide, and similarly, may comprise different thicknesses than disclosed above.

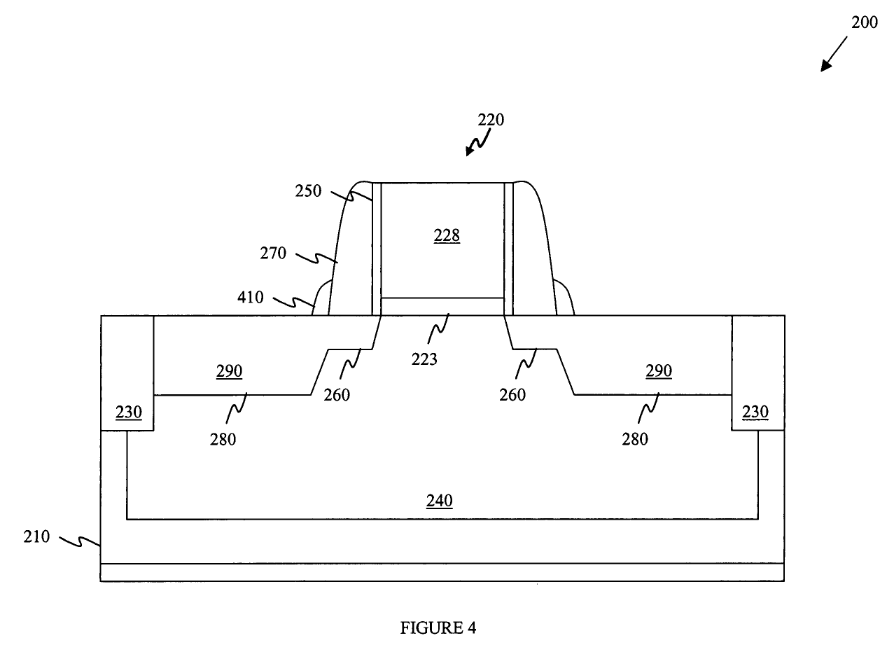

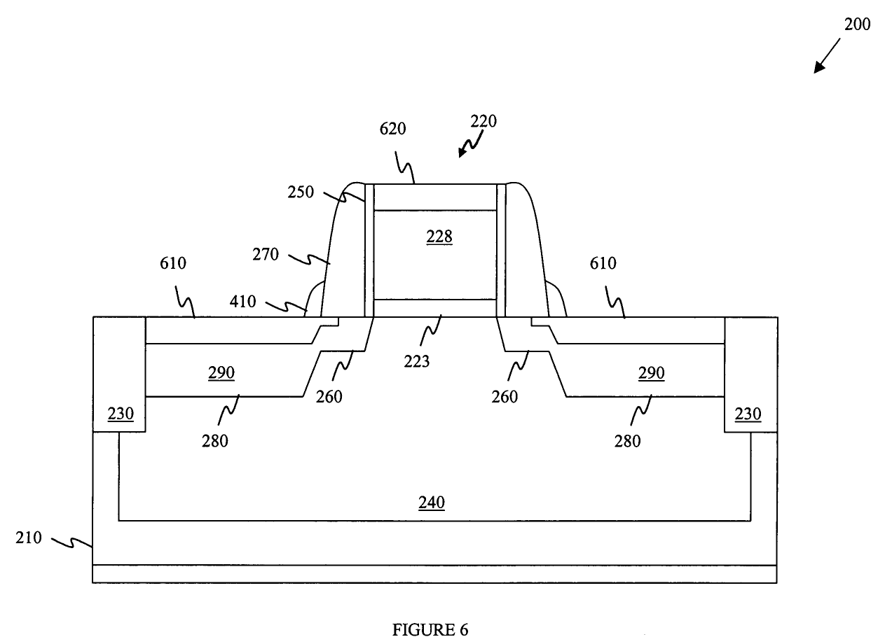

Turning now to FIG. 4, illustrated is a cross-sectional view of the partially completed semiconductor device illustrated in FIG. 3 after subjecting the layer of protective layer 310 to an etch, thereby forming protective regions 410. In the illustrative embodiment of FIG. 6 the protective regions 410 are located proximate a base of the sidewall spacers 270.

Obviously the size, and possibly shape of the protective regions 410 are a function of the original thickness of the layer of protective material 310 and its composition. Additionally, the size and shape are a function of the specific etch used to form the protective regions 410. In an exemplary embodiment the etch used to form the protective regions 410 is a conventional anisotropic etch. Among others, a dry etch or an argon plasma sputter etch could be used. Those skilled in the art understand the specifics of these etches as well as other etches that might be used, thus no further detail is given.

In one embodiment of the invention the combination of the material chosen for the layer of protective material 510 and the etch used to form the protective regions 410 from that layer, must be tailored. For example, in the instance where the layer of protective material 310 is a nitride, it is conceivable that the etch used to remove the nitride layer of protective material might also remove one or more portions of the semiconductor device 200, for instance the spacer 250. This is a perfect embodiment to use the BTBAS deposited nitride (see above) having the increased selectivity for the spacer 250. If the BTBAS deposited nitride were used for the spacer 250, a conventional nitride etch could be used to form the protective regions 410 without concern of unintentionally removing the spacer 250.

On the other hand, if an oxide were used for the protective regions 410 the aforementioned nitride selectivity issue would not be an issue. However, an etch selectivity issue does exist when an oxide is used for the protective regions 410. It is often the case that field oxides are used as the isolation regions 230 between various semiconductor devices on a wafer. Unfortunately, in this instance the conventional oxide etch used to form the protective regions 410 may possibly have a negative effect on the field oxides.

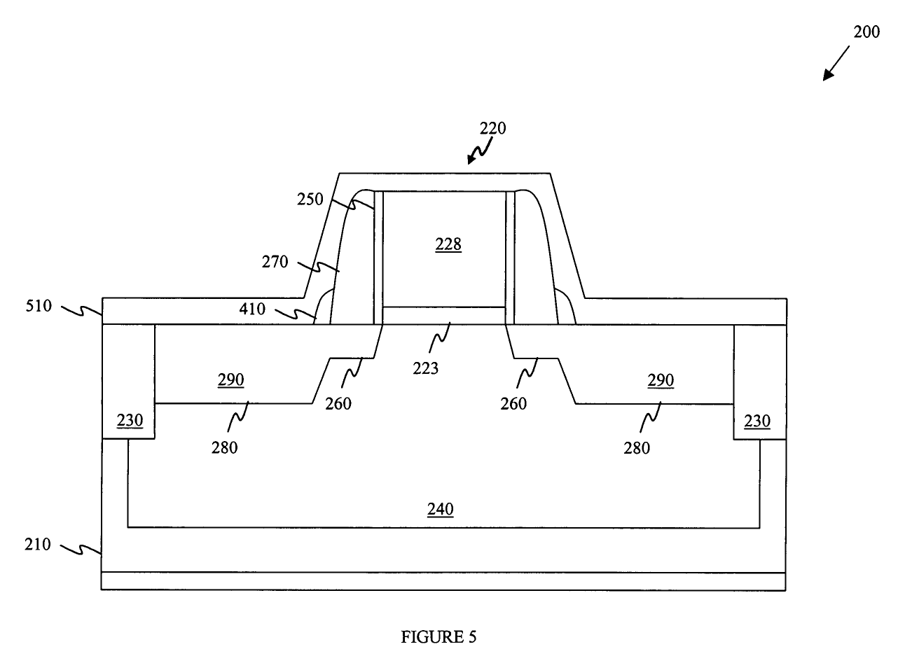

Turning now to FIG. 5, illustrated is a cross-sectional view of the partially completed semiconductor device illustrated in FIG. 4 after forming a metal layer 510 over the gate electrode layer 228 and source/drain regions 290. In an embodiment of the instant invention the metal layer 510 comprises nickel. In addition to nickel, other metals include cobalt, molybdenum, platinum, etc. For the case where nickel is used to form the metal layer 510, the thickness of the metal layer 510 is optimally between about 3 nm and about 40 nm.

Turning to FIG. 6, illustrated is a cross-sectional view of the partially completed semiconductor device illustrated in FIG. 5 after subjecting the metal layer 510 to an anneal, thereby causing the metal layer 510 to react with the underlying silicon regions to form metal silicide regions 610, 620. It should be noted that no reaction takes place between the metal layer 510 and the sidewall spacers 270. Following the formation of the metal silicide regions 610, 620, the unreacted metal is chemically removed resulting in a device similar to that shown in FIG. 6.

In the same step or an additional step an etch may or may not be used to remove the protective regions 410 from the substrate 210. In the case where the protective regions 410 are nitride protective regions a simple hot phosphoric acid process could be used. In the case where the protective regions 410 are oxide protective regions a light hydrofluoric acid process could be used. If another material were used for the protective regions 410, which is very possible, the etch could be easily tailored for that material. It should be noted that certain instances might exist where the protective regions 410 remain on the substrate 210 and provide no detrimental effects to the partially completed semiconductor device 200 at all. After removing the protective regions 410 a semiconductor device similar to the semiconductor device 100 illustrated in FIG. 1 might result.

The above described metal silicide formation process can be used for both NMOS and PMOS transistors, and particularly when forming CMOS transistors. In the case of NMOS transistors, the above described process minimizes the formation of metal silicide regions under the sidewall spacers 270, thereby reducing the aforementioned excessive encroachment defects. In the case of PMOS transistors, no benefits are known to exist at this time, however, no known drawbacks are known to exist at this time either. Therefore, the process of the present invention is very useful in a conventional CMOS process flow.

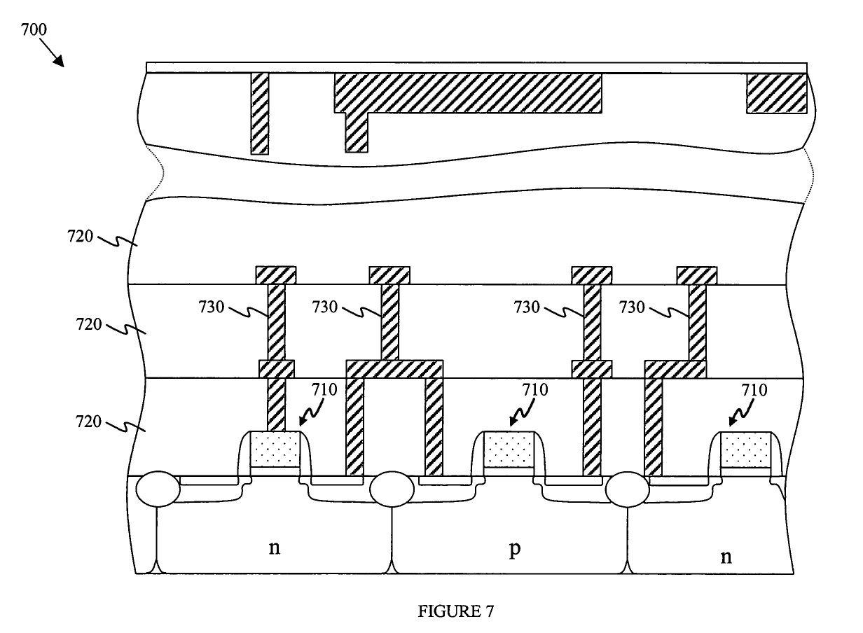

Referring finally to FIG. 7, illustrated is a sectional view of a conventional integrated circuit (IC) 700 incorporating a semiconductor device 710 constructed according to the principles of the present invention. The IC 700 may include devices, such as transistors used to form CMOS devices, BiCMOS devices, Bipolar devices, or other types of devices. The IC 700 may further include passive devices, such as inductors or resistors, or it may also include optical devices or optoelectronic devices. Those skilled in the art are familiar with these various types of devices and their manufacture. In the particular embodiment illustrated in FIG. 7, the IC 700 includes the semiconductor devices 710 having dielectric layers 720 located thereover. Additionally, interconnect structures 730 are located within the dielectric layers 720 to interconnect various devices, thus, forming the operational integrated circuit 700.

Although the present invention has been described in detail, those skilled in the art should understand that they can make various changes, substitutions and alterations herein without departing from the spirit and scope of the invention in its broadest form.

What is claimed is:

1. A method for manufacturing a semiconductor device, comprising:
forming source/drain regions in a substrate, the source/drain regions located proximate a gate structure having sidewall spacers and positioned over the substrate;
modifying a footprint of the sidewall spacers by forming protective regions proximate a base of the sidewall spacers; and
forming metal silicide regions in the source/drain regions.

2. The method as recited in claim 1 wherein modifying a footprint includes forming a layer of protective material over the gate structure having sidewall spacers and the source/drain regions, and subjecting the layer of protective material to an anisotropic etch, thereby leaving the protective regions proximate the base of the sidewall spacers.

3. The method as recited in claim 2 wherein the layer of protective material has a thickness ranging from about 2 nm to about 5 nm.

4. The method as recited in claim 1 wherein the protective regions are nitride protective regions.

5. The method as recited in claim 1 wherein the protective regions are oxide protective regions.

6. The method as recited in claim 1 wherein forming metal silicide regions includes forming a metal layer over the source/drain regions and reacting the metal layer with the source/drain regions to form the metal silicide regions in the source/drain regions.

7. The method as recited in claim 1 further including removing the protective regions after forming the metal silicide regions.

8. The method as recited in claim 1 wherein forming metal silicide regions includes forming nickel silicide regions.

9. A method for manufacturing an integrated circuit, comprising:
creating semiconductor devices over a substrate, including;
forming source/drain regions in the substrate, the source/drain regions located proximate a gate structure having sidewall spacers and positioned over the substrate;
modifying a footprint of the sidewall spacers by forming protective regions proximate a base of the sidewall spacers; and
forming metal silicide regions in the source/drain regions; and
forming interconnects within dielectric layers located over the substrate for electrically contacting the semiconductor devices.

10. The method as recited in claim 9 wherein modifying a footprint includes forming a layer of protective material over the gate structure having sidewall spacers and the source/drain regions, and subjecting the layer of protective material to an anisotropic etch, thereby leaving the protective regions proximate the base of the sidewall spacers.

11. The method as recited in claim 10 wherein the layer of protective material has a thickness ranging from about 2 nm to about 5 nm.

12. The method as recited in claim 9 wherein the protective regions are nitride or oxide protective regions.

13. The method as recited in claim 9 wherein forming metal silicide regions includes forming nickel silicide regions.

14. A semiconductor device, comprising:
a gate structure having sidewall spacers located over a substrate;
source/drain regions located in the substrate and proximate the gate structure; and
metal silicide regions located in the source/drain regions, the metal silicide regions having a main portion and an offset portion.

15. The semiconductor device as recited in claim 14 wherein the offset has a substantially stepped cross-section.

16. The semiconductor device as recited in claim 15 wherein at least one step of the metal silicide regions is located at least partially under the sidewall spacers.

17. The semiconductor device as recited in claim 14 wherein the metal silicide regions each have substantially two-stepped cross-sections, and wherein the step depths depend on a metal layer used to form them.

18. The semiconductor device as recited in claim 14 further including protective regions located proximate a base of the sidewall spacers.
